(19) United States
(12) Patent Application Publication
(10) Pub. No.: US 2025/0089547 A1
(43) Pub. Date: Mar. 13, 2025

(54) ORGANIC PHOTOVOLTAIC MATERIALS, DEVICES, AND METHODS

(71) Applicant: Florida State University Research Foundation, Inc., Tallahassee, FL (US)

(72) Inventors: Vincent O. Eze, Tallahassee, FL (US); Okenwa Okoli, Tallahassee, FL (US)

(21) Appl. No.: 18/960,568

(22) Filed: Nov. 26, 2024

Related U.S. Application Data
(62) Division of application No. 18/451,350, filed on Aug. 17, 2023.
(60) Provisional application No. 63/399,895, filed on Aug. 22, 2022.

(51) Int. Cl. H10K 85/10; H10K 30/30; H10K 30/50; H10K 71/12; H10K 85/60

(52) U.S. Cl. CPC H10K 85/113; H10K 85/626; H10K 85/657; H10K 30/30; H10K 30/50; H10K 71/12

(57) ABSTRACT

Organic photovoltaic materials (OPV) and devices using the same are provided, as well as methods of fabricating and using the same. An OPV material can be used as a photo-absorbing layer for mechanoluminescent (ML) light (e.g., in a flexible organic ML photodiode). The OPV material can include, for example, a blend of a donor polymer (e.g., P3HT) and a non-halogenated, non-fullerene acceptor (e.g., Y6).

### CROSS-REFERENCE TO RELATED APPLICATION

The present application is a divisional application of U.S. application Ser. No. 18/451,350, filed Aug. 17, 2023, which claims the benefit of U.S. Provisional Application Ser. No. 63/399,895, filed Aug. 22, 2022, the disclosure of both of which are hereby incorporated by reference in their entirety, including all figures, tables, and drawings.

### GOVERNMENT SUPPORT CLAUSE

This invention was made with government support under 1950500 awarded by The National Science Foundation. The government has certain rights in this invention.

### BACKGROUND

Structural health monitoring (SHM) can be an important tool for ensuring safety and integrity while detecting the progression of damage within engineering structures to estimate expected failure. This is typically done over time through periodically sampled response measurements to monitor changes in material and geometrical properties of a given system. For example, a commercial aircraft typically travels at around 580 miles per hour (mph), and any impact at this speed could cause damage to the material. If such damage goes unnoticed, it can progress and further risk ultimate failure or the lives of those on-board on the aircraft. Because of situations like this, there is a demand for a real-time SHM device within damage-prone systems.

### BRIEF SUMMARY

Embodiments of the subject invention provide novel and advantageous organic photovoltaic materials (OPV) and devices using the same. An OPV material can be used as a photo-absorbing layer for mechanoluminescent (ML) light (e.g., in a flexible organic ML photodiode). The OPV material can include, for example, a blend of a donor polymer (e.g., poly(3-hexylthiophene-2,5-diyl (P3HT)) and a non-halogenated, non-fullerene acceptor (e.g., Y6 (which can also be referred to as BTP-4F)). For example, the OPV material can be a blend of P3HT and Y6, which can be denoted as P3HT:Y6. The broad ultraviolet-visible (UV) to near-infrared (NIR) light absorption and excellent charge transport efficiency make P3HT:Y6 active materials excellent for a light absorbing layer to detect photon emission from the ML layer in flexible organic photodiodes (e.g., for sensing and/or structural health monitoring (SHM)).

In an embodiment, a composite material can comprise a donor polymer and a non-fullerene acceptor (NFA). A weight ratio of donor polymer to NFA (donor polymer: NFA) can be in a range of, for example, from 0.5:1 to 1.5:1 (e.g., 1:1 or about 1:1). The NFA can be a non-halogenated NFA. The donor polymer can be dispersed (e.g., evenly dispersed or substantially evenly dispersed) in the NFA, or the NFA can be dispersed (e.g., evenly dispersed or substantially evenly dispersed) in the donor polymer. The donor polymer can be P3HT and/or the NFA can be Y6. The non-fullerene acceptor is a non-halogenated non-fullerene acceptor. The composite material can be in the form of a film (e.g., a flexible film), such as a bulk heterojunction film.

In another embodiment, a device can comprise: an OPV layer comprising a composite material as disclosed herein; a first electrode disposed on the OPV layer; a charge transport layer disposed under the OPV layer; and a second electrode disposed under the charge transport layer. The OPV layer can be disposed between the charge transport layer and the first electrode, and the charge transport layer can be disposed between the second electrode and the OPV layer. The device can further comprise a substrate on which the second electrode is disposed, and the second electrode can be disposed between the substrate and the charge transport layer. The charge transport layer can be an electron transporting layer. The second electrode can comprise or be a transparent electrode (e.g., indium tin oxide); the charge transport layer can comprise or be SnO₂; and/or the first electrode can comprise or be silver, gold, or a combination thereof. The second electrode can be in direct physical contact with the charge transport layer; the charge transport layer can be in direct physical contact with the OPV layer; and/or the OPV layer can be in direct physical contact with the first electrode. The device can be flexible. The OPV can exhibit a rectification ratio in a range of from 3.6×10³ to 4×10³, and/or the device can have a response time of 100 milliseconds (ms) or less when exposed to a 470 nanometer (nm) light pulse. The device can further comprise a layer comprising an ML material. The layer comprising the ML material can be disposed on (and optionally in direct physical contact with) the first electrode, the OPV layer, the charge transport layer, and/or the second electrode. The device can be a sensor (e.g., a pressure sensor).

In another embodiment, a method of fabricating a composite material can comprise: providing a mixture comprising a liquid, a donor polymer, and an NFA; disposing the mixture on a surface; and removing at least a portion of the liquid (e.g., all of the liquid) from the mixture. The liquid can be a solvent (e.g., a polar organic solvent). The surface can comprise or be a substrate or a charge transport layer. The disposing of the mixture on the surface can comprise spin-coating the mixture on the surface. The removing of the at least a portion of the liquid can comprise annealing the mixture. The donor polymer and the NFA can have any of the features disclosed herein.

### BRIEF DESCRIPTION OF DRAWINGS

FIG. 1(a) shows the molecular structure of poly(3-hexylthiophene-2,5-diyl) (P3HT)

FIG. 1(b) shows the molecular structure of (2,2′-((2Z,2′Z)-((12,13-bis(2-ethylhexyl)-3,9-diundecyl-12,13-dihydro-[1,2,5]thiadiazolo[3,4-e]thieno[2,″3″: 4′,5′]thieno[2′,3′:4,5]pyrrolo[3,2-g]thieno[2′,3′:4,5]thieno[3,2]indole-2,10-diyl)bis(methanylylidene))bis(5,6-difluoro-3-oxo-2,3-dihydro-1H-indene-2,1-diylidene))dimalononitile) (Y6).

FIG. 1(c) shows a representation of a method for preparing a P3HT:Y6 film, according to an embodiment of the subject invention.

FIG. 2(a) shows a plot of normalized absorbance versus wavelength (in nanometers (nm)), showing an absorption spectrum for a P3HT film.

FIG. 2(b) shows a plot of normalized absorbance versus wavelength (in nm), showing an absorption spectrum for a Y6 film.

FIG. 2(c) shows a plot of normalized absorbance versus wavelength (in nm), showing an absorption spectrum for a P3HT:Y6 film.

FIG. 2(d) shows a plot of normalized absorbance versus wavelength (in nm), showing an absorption spectrum for a P3HT film, a Y6 film, and a P3HT:Y6 film. The curve with the highest normalized absorbance value at 500 nm is for P3HT; the curve with the second-highest normalized absorbance value at 500 nm is for P3HT:Y6; and the curve with the lowest normalized absorbance value at 500 nm is for Y6.

FIG. 3(a) shows an atomic force microscope (AFM) image of a P3HT film. The scale bar is 1.0 micrometer (μm).

FIG. 3(b) shows an AFM image of a Y6 film. The scale bar is 1.0 μm.

FIG. 3(c) shows an AFM image of a P3HT:Y6 film. The scale bar is 1.0 μm.

FIG. 4(a) shows a schematic view of a device, according to an embodiment of the subject invention.

FIG. 4(b) shows an image of a P3HT:Y6 photodetector, according to an embodiment of the subject invention.

FIG. 4(c) shows an energy level diagram for indium tin oxide (ITO), tin oxide (SnO₂), Y6, P3HT, and silver (Ag). The energy values are presented in electron Volts (eV).

FIG. 4(d) shows a plot of current (in amps (A)) versus voltage (in Volts (V)), showing the I-V characteristics of the device shown in FIG. 4(a) in the dark and under white illumination at 100 milliwatts per square centimeter (mW/cm²). The curve with the highest current value at 0.0 V is for the light condition; and the curve with the lowest current value at 0.0 V is for the dark condition.

FIG. 5(a) shows a plot of photovoltage (in arbitrary units (a.u.)) versus time (in seconds (sec)), showing on-off cycles of a P3HT:Y6 photodetector under 470-nm pulse light from a light-emitting diode at a frequency of 5 Hertz (Hz).

FIG. 5(b) shows an enlarged portion of the plot from FIG. 5(a).

FIG. 5(c) shows a plot of photovoltage (in a.u.) versus time (in sec), showing on-off cycles of a P3HT:Y6 photodetector under 470-nm pulse light from a light-emitting diode at a frequency of 50 Hz.

FIG. 5(d) shows an enlarged portion of the plot from FIG. 5(c).

FIG. 6(a) shows a portion of the plot from FIG. 5(a), with rise and decay times included.

FIG. 6(b) shows an image of one side (i.e., the front) of a mechanoluminescent-P3HT:Y6 pressure sensor, according to an embodiment of the subject invention.

FIG. 6(c) shows an image of an opposite side (i.e., the back) of the mechanoluminescent-P3HT:Y6 pressure sensor of FIG. 6(b).

FIG. 6(d) shows a plot of stroke (in millimeters (mm)) versus time (in sec), showing a three-point bending test of the mechanoluminescent-P3HT:Y6 pressure sensor from FIGS. 6(b) and 6(c). A suitable loading rate was 1.5 mm/s, and the sensor was subjected to 200 loading cycles. The solid curve are for the displacement while the data points (clustered in some areas) are for the sensor response.

FIG. 7(a) shows a plot of photovoltage (in a.u.) versus time (in sec), showing on-off cycles of a P3HT:Y6 photodetector under green LED illumination at a frequency of 5 Hz.

FIG. 7(b) shows an enlarged portion of the plot from FIG. 7(a).

FIG. 7(c) shows a plot of photovoltage (in a.u.) versus time (in sec), showing on-off cycles of a P3HT:Y6 photodetector under red LED illumination at a frequency of 5 Hz.

FIG. 7(d) shows an enlarged portion of the plot from FIG. 7(c).

FIG. 8 shows an image of a setup used for a three-point bending test (e.g., used to obtain the test results in FIG. 6(d)).

### DETAILED DESCRIPTION

Embodiments of the subject invention provide novel and advantageous organic photovoltaic materials (OPV) and devices using the same. An OPV material can be used as a photo-absorbing layer for mechanoluminescent (ML) light (e.g., in a flexible organic ML photodiode). The OPV material can include, for example, a blend of a donor polymer (e.g., poly(3-hexylthiophene-2,5-diyl(P3HT)) and a non-halogenated, non-fullerene acceptor (e.g., Y6 (which can also be referred to as BTP-4F)). For example, the OPV material can be a blend of P3HT and Y6, which can be denoted as P3HT:Y6. The broad ultraviolet-visible (UV) to near-infrared (NIR) light absorption and excellent charge transport efficiency make P3HT:Y6 active materials excellent for a light absorbing layer to detect photon emission from the ML layer in flexible organic photodiodes (e.g., for sensing and/or structural health monitoring (SHM)).

Flexible mechanoluminescent-organic photodiodes include a photodiode disposed on top of an ML layer that emits light when it experiences mechanical force, such as pressure. The absorber layer, also known as the active layer, in the photodiode is responsible for light absorption and charge transport to produce electric signals. In practice, the ML layer can respond to load or damage, and emit light into the photodiode, which can then convert the light into electric signals. When coupled with software and/or a data acquisition system, the sensor's data can be received and interpreted.

Perovskites have been considered for use in the active layer, due to their optoelectronic properties such as high charge carrier mobility, small exciton binding energy, large carrier diffusion lengths, ambipolar and tunable bandgap, and external quantum efficiency (EQE) (over 80%). However, at least some perovskites, such as organic-inorganic lead halide perovskites, can become chemically unstable and ultimately degrade when exposed to environmental humidity, high temperatures, and/or light, therefore making their commercialization difficult.

The power conversion efficiency degradation rate for some organic-inorganic lead halide perovskites is above 0.1% per hour (%/h), which is orders of magnitude higher than organic photovoltaics (OPVs; about 10⁻³ %/h) and inorganic crystalline silicon (c-Si) and cadmium indium gallium selenide (CIGS; about 10⁻⁵ %/h). This suggests that the requirement for chemically stable, robust, and efficient organic photoactive semiconductor materials is important for advancing the next generation of optoelectronic devices.

In order to address the issue of instability mentioned above, bulk heterojunction (BHJ) OPV active layers based on a blend of a p-type organic semiconductor have been exposed as a donor (D) with an n-type organic semiconductor as acceptor (A). D-A materials can be used as efficient light-absorbing layers for solar cells, photodetectors, transistors, and radiation detection. A notable application of organic D-A materials is for the fabrication of solar cells. P3HT, buckminsterfullerene (C60), and its derivative phenyl-C₆₁-butyric acid methyl ester (PCBM) can be used as D-A materials for BHJ OPVs (see also, e.g.; Yu et al., J. Science 1995, 270, (5243), 1789-1791; Halls et al. Applied Physics Letters 1996, 68, (22), 3120-3122; Thompson et al., Angewandte chemie international edition 2008, 47, (1), 58-77; and Yuan et al., Joule 2019, 3, (4), 1140-1151; all of which are hereby incorporated herein by reference in their entireties).

OPVs are lightweight and cheap, and have the capability to be constructed into flexible and semitransparent devices. However, the development of OPVs is hampered by their large charge recombination in the D-A blend and low power conversion efficiencies. Attempts have been made to improve the blend morphology control, improve the charge-carrier mobility, reduce the charge recombination, optimize the device geometry, and improve the power conversion efficiency of OPVs. Because of the issue with the power conversion efficiency of OPVs, low-bandgap non-fullerene acceptors (NFAs) have been developed. NFAs offer a compelling way to improve the performance of OPVs due to their tunable energy levels, high charge carrier mobility, and strong absorption in the near-infrared region (NIR). One NFA is (2,2′-((2Z,2′Z)-((12,13-bis(2-ethylhexyl)-3,9-diundecyl-12,13-dihydro-[1,2,5]thiadiazolo[3,4-e]thieno[2,″3″:4′,5′]thieno[2′,3′:4,5]pyrrolo[3,2-g]thieno[2′,3′:4,5]thieno[3,2]indole-2,10-diyl)bis(methanylylidene))bis(5,6-difluoro-3-oxo-2,3-dihydro-1H-indene-2,1-diylidene))dimalononitile) (referred to as “Y6”), which can be synthesized from the central unit of fused dithienothiophen [3,2b]-pyrrolobenzothiadiazole, TPBT (see also Yuan et al., supra.). A Y6 acceptor molecule and a conjugated polymer (PM6) as p-type donor can be applied as the active layer in a BHJ organic solar cell (power conversion efficiency of 15.3%). Y6 as an acceptor and PBDB-TF as p-type donor can achieve power conversion efficiencies of 16% (see also Cui et al., Nature communications 2019, 10, (1), 1-8; which is hereby incorporated herein by reference in its entirety). The high power conversion efficiency exhibited by PM6:Y6 BHJ solar cells can be attributed to the extraordinarily long diffusion length, which is an order of magnitude larger than typical values for organic solar cells. The power conversion efficiency of other NFA acceptor Y6 OPV systems can be higher (e.g., over 17%; see also; Wu et al., Journal of Energy Chemistry 2021, 61, 29-46; and Ma et al., National science review 2021, 8, (8), nwaa305; both of which are hereby incorporated herein by reference in their entireties).

Related art ML-perovskite pressure sensors suffer a number of disadvantages. For example, perovskite semiconductor materials can be susceptible to degradation under extreme conditions, which can make it difficult to commercialize the technology in its present state. There remains a need in the art for OPV materials that are robust, including under extreme conditions, have a broader absorption spectrum (e.g., from the ultraviolet to infrared region), or a combination thereof. There also remains a need for sensors that incorporate these materials.

In an embodiment of the subject invention, a composite material can comprise a donor polymer and an NFA, where the donor polymer is dispersed (e.g., evenly dispersed or substantially evenly dispersed) in the NFA and/or the NFA is dispersed (e.g., evenly dispersed or substantially evenly dispersed) in the donor polymer. A weight ratio of donor polymer to NFA can be in a range of, for example, from 0.5:1 to 1.5:1 (donor polymer:NFA) (e.g., a ratio of 1:1 or about 1:1). The donor polymer can be a conjugated polymer (e.g., P3HT). The NFA can be a non-halogenated NFA (e.g., Y6). The composite material can be in the form of a film (e.g., a BHJ film), which can be a flexible film.

In an embodiment, a method of fabricating a composite material can comprise: providing a mixture comprising a liquid (e.g., a solvent), a donor polymer, and the an NFA; disposing the mixture on a surface; and removing at least a portion of the liquid from the mixture. The liquid can comprise (or be) a polar organic liquid (e.g., 1,2-dichlorobenzene). The surface can be, for example, a substrate or a charge transport layer. The disposing of the mixture on the surface can comprise spin-coating the mixture on the surface. The removing of the at least a portion of the liquid can comprise annealing the mixture.

In an embodiment, a device can comprise: a first electrode; an OPV layer comprising a composite material as disclosed herein; a charge transport layer; and a second electrode. The charge transport layer can be disposed between the second electrode and the OPV layer, and/or the OPV layer can be disposed between the charge transport layer and the first electrode. The device can further comprise a substrate on which the second electrode is disposed. The second electrode can be a transparent electrode (e.g., indium tin oxide (ITO)). The charge transport layer can be an electron transporting layer (e.g., SnO₂). The first electrode can comprise a conductive material (e.g., silver (Ag), gold (Au), platinum (Pt), copper (Cu), or a combination thereof). The second electrode can be in direct physical contact with the charge transport layer; the charge transport layer can be in direct physical contact with the OPV layer; and/or the OPV layer can be in direct physical contact with the first electrode. The device can be flexible. The OPV layer can exhibit a rectification ratio in a range of, for example, from 3.6×10³ to 4×10³ (e.g., from 3.8×10³ to 3.85×10³). The device can have a response time, when exposed to a 470 nm light pulse, of 100 ms or less (e.g., 95 ms or less). The device can further comprise a ML material (or ML layer) disposed on (and optionally in direct physical contact with) the first electrode, the OPV layer, the charge transport layer, and/or the second electrode. The ML layer can comprise, for example, ZnS:Cu. The ML layer can be dispersed in an elastomer (e.g., PDMS). The device can be, for example, a sensor, such as a pressure sensor.

In an embodiment, a method of sensing can comprise: providing a sensor as disclosed herein; and exposing the sensor to at least one force effective to cause an emission of photons by the ML layer, where the photons are converted to one or more electric signals by the first electrode, the OPV layer, the charge transport layer, the second electrode, or a combination thereof. The at least one force can comprise pressure, and/or the one or more electric signals can comprise one or more electric currents. The method can further comprise correlating the one or more electric currents to the at least one force. The method can further comprise monitoring the one or more electric currents.

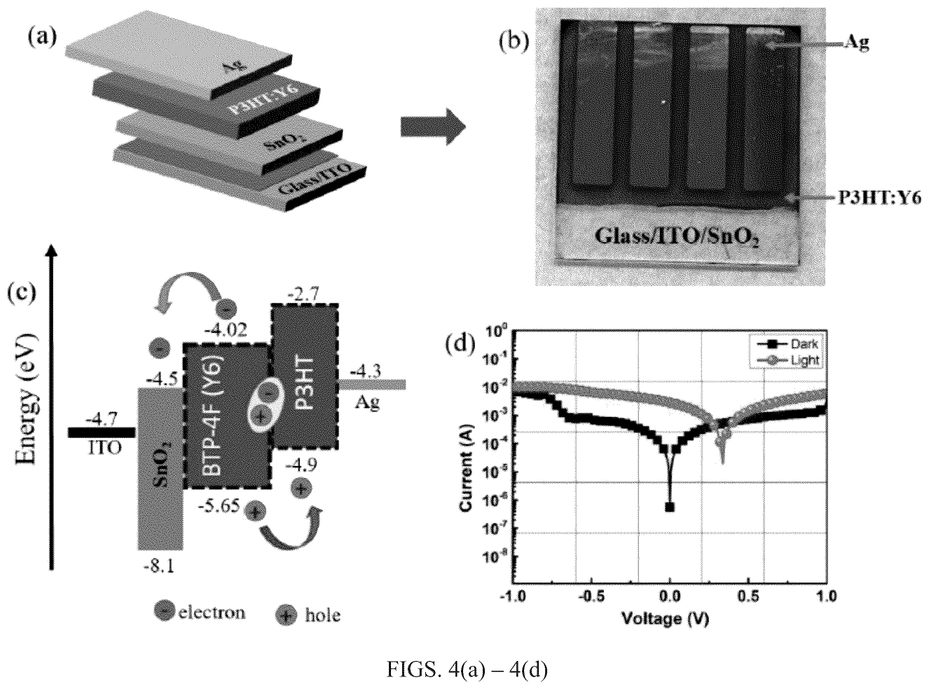

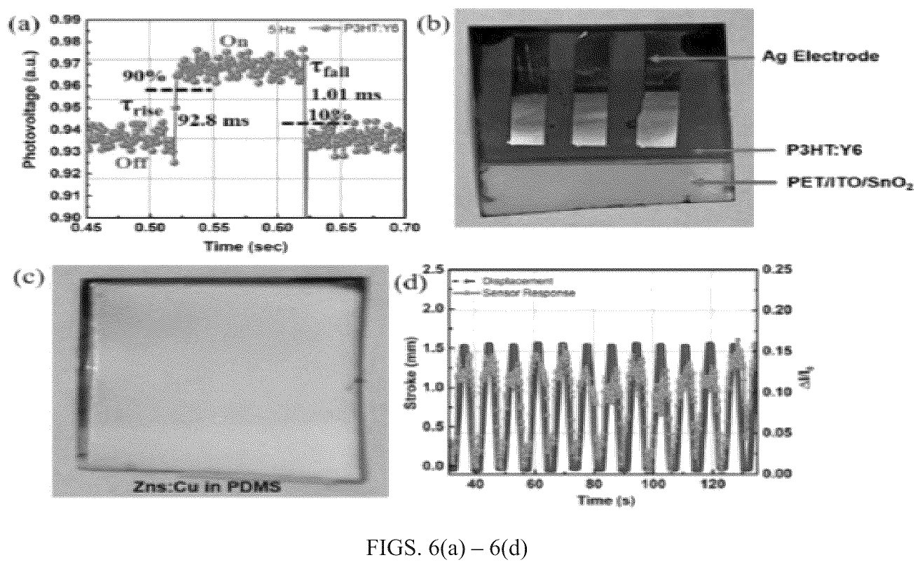

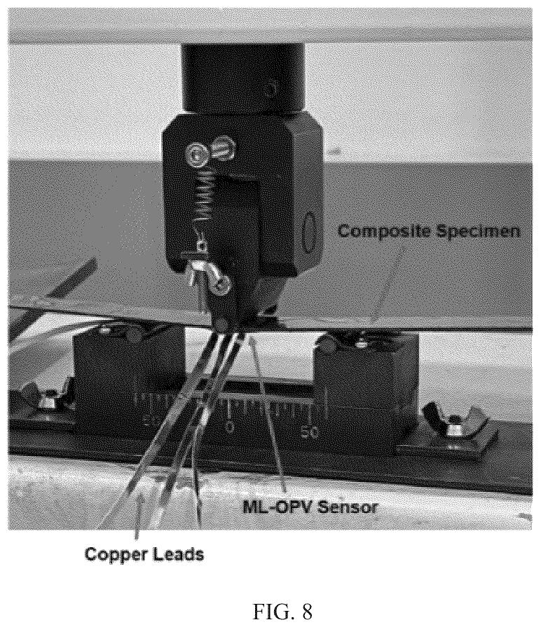

Referring to FIGS. 4(a)-4(d), in an embodiment, a device can have a vertical device structure of a first electrode (e.g., Ag, Au, Pt, Cu, etc.) disposed on an OPV material (e.g., P3HT:Y6), which can be disposed on a charge transport layer (e.g., a metal oxide such as tin oxide (SnO₂)), which can be disposed on a second electrode (e.g., a transparent electrode, such as ITO). For example, the first electrode can be in direct physical contact with the OPV material, which can be in direct physical contact with the charge transport layer, which can be in direct physical contact with the second electrode. The current-voltage measurements in FIG. 4(d) show that the P3HT:Y6 OPV exhibited an excellent rectification ratio of 3.82×10³, while the response time measurement demonstrated that the devices had an impressive response speed of 92.8 milliseconds (ms). Also, a three-point bending test unveiled that, for some embodiments, the device possessed excellent stability after several cycles (see also FIGS. 6(d) and 8). In an embodiment, a pressure sensor can include an OPV as disclosed herein. For example, a pressure sensor can include a zinc sulfide (ZnS):Cu ML material and a P3HT:Y6 BHJ OPV.

In some embodiments, P3HT:Y6 (e.g., P3HT:Y6) can be used as an OPV for a photo-absorbing layer for ML light. The photoelectric performance of the P3HT:Y6 BHJ OPV was assessed using a simple vertical device structure of ITO/SnO₂/P3HT:Y6/Ag (the Ag as an electrode). The device exhibited an excellent rectification ratio of 3.82×10³ and a stable and repeatable on/off electrical signal at 5 Hz with a response speed of 92.8 ms. A mechanical three-point bending test performed on several embodiments revealed that the light emitted from the ML layer was efficiently collected by the OPV active layer and converted into distinct electrical signals for structural health monitoring applications.

Embodiments of the subject invention include composite materials. The composite materials can include a polymer donor and a non-fullerene acceptor. The polymer donor and the non-fullerene acceptor can be present in the composite material at a weight ratio in a range of, for example, 0.5:1 to 1.5:1 (e.g., about 0.5:1 to about 1.5:1) (polymer donor:non-fullerene acceptor). In an embodiment, the weight ratio can be 1:1 or about 1:1 (polymer donor:non-fullerene acceptor). That is, the amount of polymer donor can exceed the amount of non-fullerene acceptor in the composite material, or vice versa. When the polymer donor is present at a greater amount (by weight), then the non-fullerene acceptor can be dispersed in the polymer donor. When the non-fullerene acceptor is present at a greater amount (by weight), then the polymer donor can be dispersed in the non-fullerene acceptor. The polymer donor can be evenly (or substantially evenly) dispersed in the fullerene acceptor, or the non-fullerene acceptor can be evenly (or substantially evenly) dispersed in the polymer donor. The polymer donor can be a conjugated polymer donor, such as P3HT. The non-fullerene acceptor can be a non-halogenated acceptor, such as Y6 (BTP-4F). The composite material can be in any form (e.g., a film or a BHJ film; and such a film can be flexible).

In an embodiment, a method of forming a composite material can include: providing a mixture comprising a liquid (e.g., a solvent), the polymer donor, and the non-fullerene acceptor; disposing the mixture on a surface; and removing at least a portion of the liquid from the mixture. Any liquid may be used, such as a polar organic liquid (e.g., 1,2-dichlorobenzene). The mixture can be deposited on any surface, such as a layer of a device (e.g., an optoelectronic device). The surface can comprise a substrate and/or a charge transport layer. Any reasonable method can be used to dispose the mixture on a surface. For example, the disposing of the mixture on the surface can comprise spin-coating the mixture on the surface. The removing of the at least a portion of the liquid can comprise heating the mixture (e.g., annealing the mixture).

Embodiments of the subject invention provide devices that include composite materials as disclosed herein. A device can include a first electrode, a charge transport layer, an OPV layer comprising the composite material, and a second electrode. The charge transport layer can be arranged between the second electrode and the OPV layer, and the OPV layer can be arranged between the charge transport layer and the first electrode. The second electrode and the charge transport layer can be in direct physical contact with each other; and/or the charge transport layer and the OPV layer can be in direct physical contact with each other; and/or the OPV layer and the first electrode can be in direct physical contact with each other. The device can also include a substrate, and the second electrode can be arranged on the substrate. The substrate can be transparent (e.g., glass and/or a glass electrode). Any conductive material can be used in the first and second electrodes. For example, the second electrode can comprise ITO, and/or the first electrode can include Ag, Au, or a combination thereof. The charge transport layer can transport any type of charge. In an embodiment, the charge transport layer is an electron transporting layer (e.g., a layer that is or that comprises SnO₂). The device can be flexible (i.e., able to bend without breaking or cracking). The OPV layer can exhibit a rectification ratio in range of from 3.6×10³ to 4×10³ (or about 3.6×10³ to about 4×10³), for example from 3.8×10³ to 3.85×10³ (or about 3.8×10³ to about 3.85×10³). The device can have a response time of 100 ms or less (e.g., 95 ms or less) when exposed to a 470 nanometer (nm) light pulse.

In an embodiment, a sensor can include a device as described herein and a layer comprising an ML material. The layer comprising the ML material can be arranged on (and optionally in direct physical contact with) at least one of the first electrode, the OPV layer, the charge transport layer, and the second electrode. Any ML material can be used (e.g., ZnS:Cu). The ML material can be dispersed in an elastomer (e.g., polydimethylsiloxane (PDMS)). The sensor can be, e.g., a pressure sensor.

Embodiments of the subject invention provide methods of forming sensors. A method can include providing a device as described herein (comprising a first electrode, an OPV layer, a charge transport layer, and a second electrode); and disposing a layer comprising an ML material on the device to form the sensor. The layer comprising the ML material can be disposed on and in contact with at least one of the first electrode, the OPV layer, the charge transport layer, and the second electrode.

In an embodiment, a method of sensing can include: providing a sensor as disclosed herein; and exposing the sensor to one or more forces effective to cause an emission of photons by the layer comprising the ML material. The photons can be converted to one or more electric signals by the second electrode, the OPV layer, the charge transport layer, the second electrode, or a combination thereof. The method of sensing can sense any kind of force (e.g., the one or more forces can pressure). The one or more electric signals can comprise one or more electric currents. The method can also include correlating the one or more electric currents to the one or more forces. The method can also include monitoring the one or more electric currents.

While certain aspects of conventional technologies have been discussed to facilitate disclosure of various embodiments, applicants in no way disclaim these technical aspects, and it is contemplated that the present disclosure may encompass one or more of the conventional technical aspects discussed herein.

The present disclosure may address one or more of the problems and deficiencies of known methods and processes. However, it is contemplated that various embodiments may prove useful in addressing other problems and deficiencies in a number of technical areas. Therefore, the present disclosure should not necessarily be construed as limited to addressing any of the particular problems or deficiencies discussed herein.

The terms “a,” “an,” and “the” are intended to include plural alternatives, e.g., at least one. For instance, the disclosure of “an antisolvent”, “a triaryl amine”, and the like, is meant to encompass one, or mixtures or combinations of more than one antisolvent, triaryl amine, and the like, unless otherwise specified.

Various numerical ranges are disclosed herein. When a range of any type is disclosed or claimed herein, the intent is to disclose or claim individually each possible number that such a range could reasonably encompass, including end points of the range as well as any sub-ranges and combinations of sub-ranges encompassed therein, unless otherwise specified.

When ranges are used herein, combinations and subcombinations of ranges (e.g., any subrange within the disclosed range) and specific embodiments therein are intended to be explicitly included. When the term “about” is used herein, in conjunction with a numerical value, it is understood that the value can be in a range of 95% of the value to 105% of the value, i.e. the value can be +/−5% of the stated value. For example, “about 1 kg” means from 0.95 kg to 1.05 kg.

A greater understanding of the embodiments of the subject invention and of their many advantages may be had from the following examples, given by way of illustration. The following examples are illustrative of some of the methods, applications, embodiments, and variants of the present invention. They are, of course, not to be considered as limiting the invention. Numerous changes and modifications can be made with respect to embodiments of the invention.

### MATERIALS AND METHODS

Conjugated polymer donor (P3HT), non-halogenated fullerene acceptor (Y6), tin (II) chloride dehydrate (SnCl₂, 99.995%), anhydrous 2-methoxyethanol (99.8%), 1,2-dichlorobenzene (DCB, 99%) used in the examples were all purchased from Sigma Aldrich. All materials were used without further treatment.

### Example 1—OPV and Pressure Sensor Device Fabrication

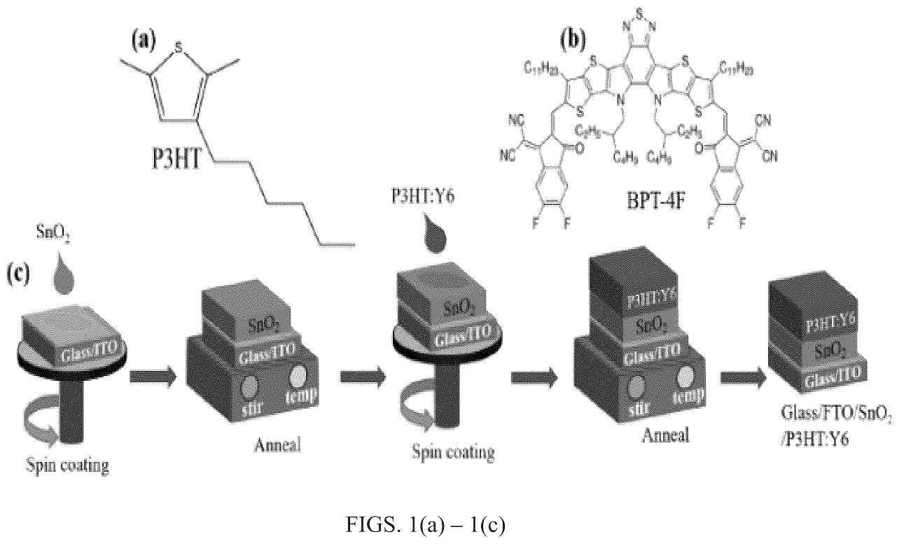

Referring to FIG. 1(c), ITO-coated glass substrates were patterned by etching with hydrochloric acid (HCl) and zinc (Zn) powder and sequentially cleaned with Hellmanex, nano-pure water, acetone, and isopropanol using a sonication machine for 10 min. The substrates were further treated with an oxygen plasma cleaner for 5 min. The SnO₂ electron transporting layer was prepared by mixing 0.2 M of SnCl₂ in an anhydrous 2-methoxyethanol. The solution was deposited on top of a clean ITO/glass substrate by spin-coating at 3000 rpm for 30 seconds (s) and annealed at 150° C. for 60 minutes (min).

Next, a 1:1 weight ratio of P3HT:Y6 blend solution was deposited atop the SnO₂ layer by spin-coating at 1500 rpm for 45 s and cured at 100° C. for 10 min in a nitrogen-filled glovebox. The P3HT:Y6 active layer solution was made by mixing 10 mg of P3HT, 10 mg of Y6 in 1 mL of 1,2-dichlorobenzene and stirred overnight at 70° C. The final devices were completed by depositing a carbon electrode using the doctor blading method.

### Example 2—OPV Pressure Sensor Fabrication

FIGS. 1(a) and 1(b) present the molecular structure of P3HT and Y6, respectively. Y6 is a new class of n-type molecular material or NFA that offers several advantages such as increased photocurrent due to a higher absorption coefficient, improved cell voltage due to a reduction in non-radiative energy losses and high device photostability over fullerene acceptors. The use of an NFA allowed for fine-tuning of side-chain orientations to match with the polymer donor, control phase separation, blend morphology, increase the external quantum efficiency (EQE) and device lifetime.

The P3HT:Y6 BHJ OPV was fabricated on top of a PET/ITO substrate following the same method described in Example 1. For the ML pressure sensor fabrication, the device was prepared as follows (see also Shohag et al., ACS Applied Nano Materials 2020, 3, (7), 6749-6756; which is hereby incorporated herein by reference in its entirety). ZnS:Cu ML material was mixed in a PDMS elastomer using a Thinky mixer. The ZnS:Cu/PDMS composite was doctor blade deposited on the other side of the flexible polyethylene terephthalate (PET) substrate. The pressure sensor was completed by thermal evaporation of the Ag electrode. The evaporated electrode was used to define the device's active area.

### Example 3—Materials and Device Characterization

The morphology of the P3HT, Y6, and P3HT:Y6 blend were characterized using atomic force microscopy (AFM, Bruker Icon scanning probe microscope (SPM)). The absorption spectra were collected using an Agilent Cary 5000. The current-voltage (I-V) measurements were obtained by a Keithley 2400 integrated with LabView under a white light light-emitting diode (LED) lamp with an intensity of 100 milliwatts per square centimeter (mW/cm²). The temporal response was obtained using a NI-6210 data acquisition device (DAQ). The signal from the DAQ (N1-6210) to the computer was boosted with Hamamatsu C7319 on a low bandwidth setting and 105 gain and powered with an Agilent E3630A at 6 Volts (V). A MATLAB software was used to collect and process the data. The light source was powered by a GwInstek GFG-8255A function generator, creating a square wave with an amplitude of 2 V to power LEDs. The cyclic 3-point bending test was performed by utilizing a Shimadzu mechanical testing system (see FIG. 8). The output current from the sensor was collected with a Keithley 2410 and a custom-built LabVIEW program.

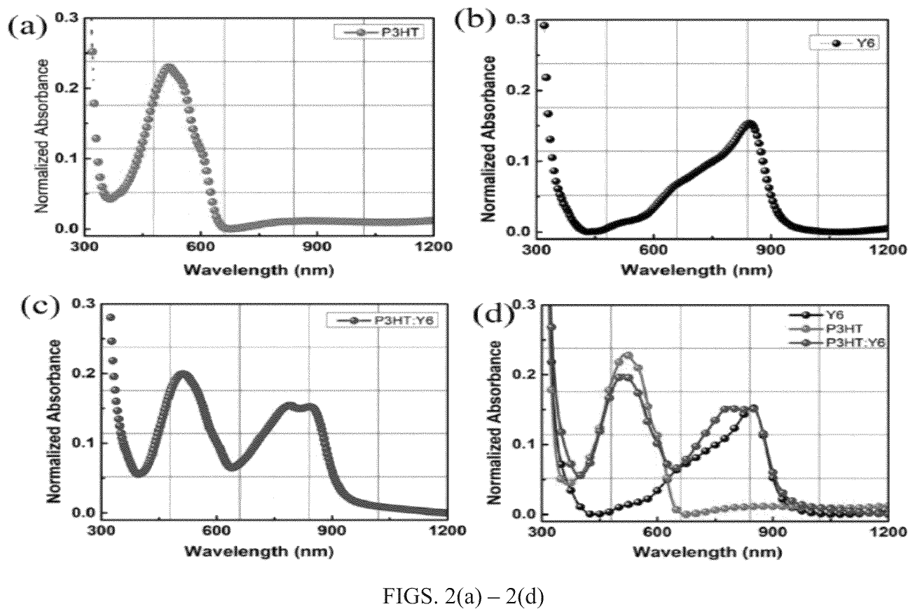

The absorption properties of P3HT film, Y6 film, and P3HT:Y6 blend deposited on top of Glass/ITO/SnO₂ substrates were measured and shown in FIGS. 2(a)-2(d). FIG. 2(a) shows the absorption spectrum of P3HT. As can be seen, the main absorption range of P3HT covered from 300 nm to 650 nm, with a characteristic absorption peak located at 516 nm. FIG. 2(c) displays the absorption spectrum of Y6. The primary absorption of Y6 film was in the range of 300 nm to 1000 nm, with a significant absorption peak located at 846 nm. Interestingly, the P3HT:Y6 blend possesses a broad absorption range from UV to the NIR region (FIGS. 2(c) and 2(d)). It was further observed that the optical bandgap of the P3HT:Y6 was around 1.30 electron Volts (eV), which was estimated from extrapolating the absorption onset of the spectrum from the NIR. Because the light source of this organic photodiode was a zinc sulfide:copper (ZnS:Cu) or zinc sulfide:manganese (ZnS:Mn) ML layer, the bandgap of the P3HT:Y6 blend must be lower than that of ZnS:Cu. Lower bandgap light-absorbing semiconductor materials can be desirable for the ML pressure sensor system.

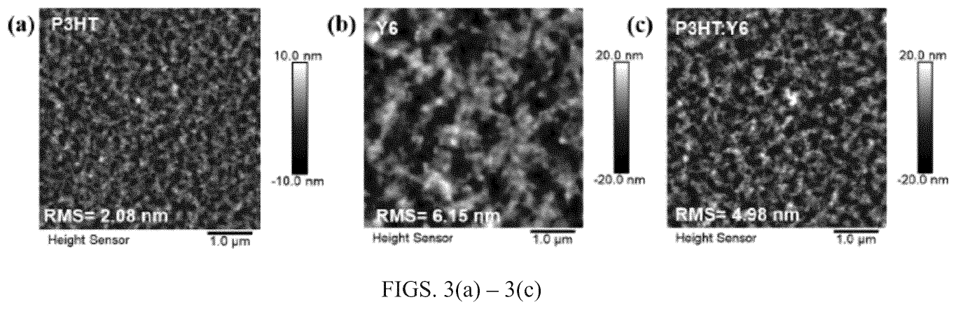

The morphological features of P3HT, Y6, and P3HT:Y6 blend were studied using an AFM. AFM height images and phases images for P3HT, Y6, and P3HT:Y6 blend are shown in FIGS. 3(a)-3(c), where the root-mean-square (RMS) roughness values were 2.08 nm, 6.15 nm, and 4.98 nm, respectively. The P3HT film showed uniformly dispersed morphology of the P3HT molecules, while the Y6 film showed morphology with several grooves and noticeable voids. It was apparent that the P3HT:Y6 blend had good miscibility, which was beneficial for the efficient dissociation of the charge carriers at the donor-acceptor interface.

Electrical Characterization—The dark and photoelectric response of the P3HT:Y6 OPV was investigated using the structure depicted in FIG. 4(a) (image of the device shown in FIG. 4(b)). The energy band diagram of the device structure is presented in FIG. 4(c). The working principle of this OPV included the following: (1) absorption of incident light leading to excitation; (2) diffusion of excitons to donor-acceptor interface; (3) separation of charges, (4) charge-carrier transport; and (5) charge-carrier collection.

The P3HT:Y6 was organized into a BHJ layer where the acceptor and donor molecules were blended throughout the active layer. Upon light absorption, excitons were diffused into the interface between donor and acceptor materials to generate the donor-acceptor charge carriers (see FIG. 4(c)). The charge carriers were separated at the interface and collected by the donor-acceptor materials. As shown in FIG. 4(c), the electron is collected by the Y6 acceptor material and transported into ITO, while the hole is extracted by the P3HT layer and then further collected by the Ag electrode.

FIG. 4(d) shows the plot for light/dark current-voltage response. Referring to FIG. 4(d), it can be seen that the dark current was lower than the light current. This must be true in a functioning device because the dark current was the current in a photodiode when there was no incident light. In other words, in the dark OPVs act as simple diodes, meaning it easily allows current to flow in one direction. Under illumination, the active layer generates a photocurrent, which should result in a higher current. Therefore, the current of the device in the dark should be lower than that under illumination. The device exhibited a dark current of 5.51×10⁻⁷ Amperes (A) and a light current of 2.85×10⁻³ A under 0 V. The light on/off ratio was determined to be 3.82×10³, suggesting excellent rectification and comparable to the values of related art organic-inorganic photodiodes.

Response speed is an essential parameter for photodiodes, which shows its capability to follow a fast varying optical signal. Fast and reproducible responses to light illumination can be vital for high-performance photodiodes for application in SHM, intelligent sensing, image sensing, and optical communication. The response time measurement was conducted as follows (see also; Adams et al., Engineering Research Express 2020, 2, (1), 015043; Eze et al., RSC Advances 2020, 10, (31), 18139-18146; and Simpson et al., The Journal of Physical Chemistry C 2020, 124, (38), 20643-20653; all of which are hereby incorporated herein by reference in their entireties).

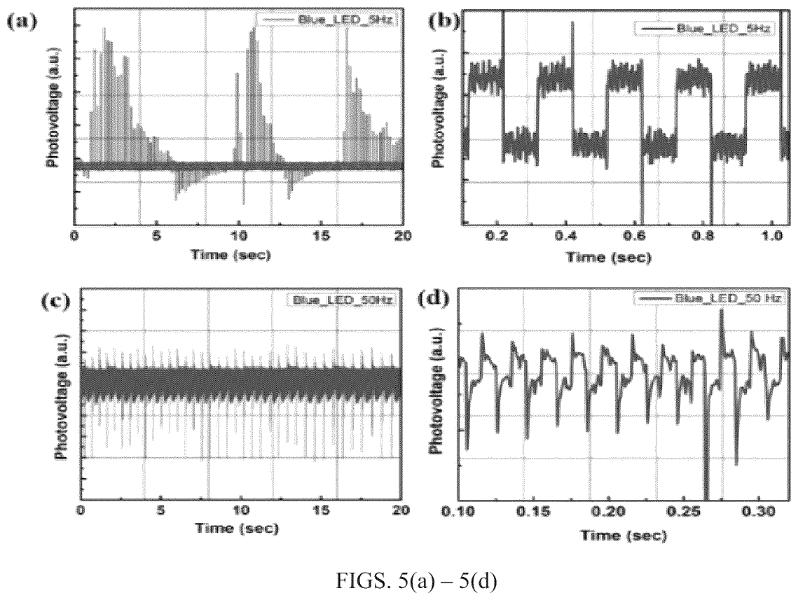

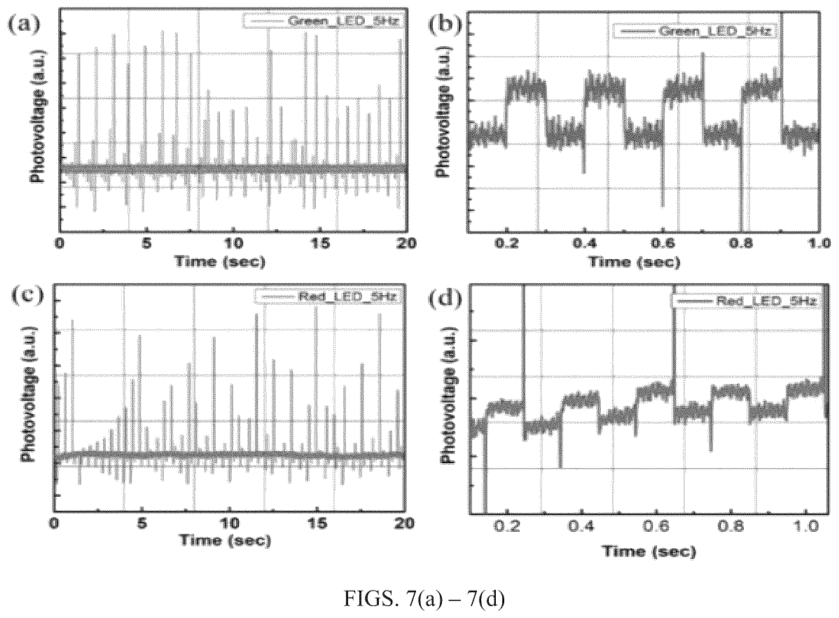

In order to test the response time, a 470 nm pulse light source was provided from an LED and driven by a function generator with square waves at a frequency of 5 Hertz (Hz) under ambient conditions. FIGS. 5(a)-5(d) show the response time measurements of the P3HT:Y6 photodiodes under 470 nm pulse light from an LED. The device displayed impressive temporal response even at a higher frequency of 50 Hz. Also investigated was the device response under 570 nm green, and 625 nm red LED illumination. FIGS. 7(a) and 7(b) show the response time measurements of the device under green LED illumination, and FIGS. 7(c) and 7(d) show the response time measurements of the device under red LED illumination. It was observed that the photodiode's response to the LEDs was agreeable to the P3HT:Y6 UV-vis absorption results, which showed broad optical absorption. Also evaluated was the response rise (τᵣᵢₛₑ) and fall (τ_{fall}) times, which were the times taken for a photodiode to reach 90% and drop to 10% of steady-state values, respectively (see also Adams et al., Eze et al., and Simpson et al., supra.). Referring to FIG. 6(a), the device showed a τᵣᵢₛₑ and τ_{fall} of 92.8 ms and 1.01 ms, respectively, which is comparable to or even higher than related art devices.

In order to investigate the performance of the P3HT:Y6 photodiodes in ML-based pressure sensors, a P3HT:Y6 photodiode was integrated with ZnS:Cu ML material (see also Shohag et al., supra.). FIGS. 6(b) and 6(c) show images of the ML-OPV pressure sensor. The ML-PDMS composite was deposited on the back of the OPV photodiode, as seen in FIG. 6(c). In principle, ML materials showed light emission due to mechanical stress; thus, as pressure is applied to the ML layer, photon emission is expected. The photons are then collected by the OPV photodiode and converted into electrical current. The current variation was monitored and correlated to the pressure applied to the device for sensing purposes. The ML emission intensity increased linearly with the increase of applied pressure.

A mechanical three-point bending test was conducted to evaluate the performance of the ML-OPV sensor for SHM applications. FIG. 8 shows the three-point bending test setup. The sensor was attached to the back surface of a carbon fiber composite sample and subjected to 200 bending cycles. A fixed 1.5 millimeter (mm) displacement was applied in each bending cycle. FIG. 6(d) shows the results of repeated bending test for 12 cycles. The sensor generated distinct and evident signals for each cycle. In addition, the sensor intensity signals showed a good correlation with the displacement applied to the composite sample. The sensor showed a steady response over the cycles, evidencing the ability of the sensor for SHM applications.

It should be understood that the examples and embodiments described herein are for illustrative purposes only and that various modifications or changes in light thereof will be suggested to persons skilled in the art and are to be included within the spirit and purview of this application.

All patents, patent applications, provisional applications, and publications referred to or cited herein are incorporated by reference in their entirety, including all figures and tables, to the extent they are not inconsistent with the explicit teachings of this specification.

What is claimed is:

1. A composite material, comprising:
a donor polymer; and
a non-fullerene acceptor,
wherein a weight ratio of donor polymer to non-fullerene acceptor is in a range of from 0.5:1 to 1.5:1, and
wherein the donor polymer is dispersed in the non-fullerene acceptor, or the non-fullerene acceptor is dispersed in the donor polymer.

2. The composite material according to claim 1, wherein the donor polymer is poly(3-hexylthiophene-2,5-diyl (P3HT).

3. The composite material according to claim 2, wherein the non-fullerene acceptor is (2,2′-((2Z,2′Z)-((12,13-bis(2-ethylhexyl)-3,9-diundecyl-12,13-dihydro-[1,2,5]thiadiazolo[3,4-e]thieno [2,″3″:4′,5′]thieno[2′,3′:4,5]pyrrolo[3,2-g]thieno[2′,3′:4,5] thieno [3,2]indole -2,10-diyl)bis(methanylylidene))bis(5,6-difluoro-3-oxo-2,3-dihydro-1H-indene-2,1-diylidene)) dimalononitile) (Y6).

4. The composite material according to claim 1, wherein the non-fullerene acceptor is Y6.

5. The composite material according to claim 1, wherein the non-fullerene acceptor is a non-halogenated non-fullerene acceptor.

6. The composite material according to claim 1, wherein the weight ratio of donor polymer to non-fullerene acceptor is about 1:1.

7. The composite material according to claim 1, wherein the donor polymer is substantially evenly dispersed in the fullerene acceptor, or the non-fullerene acceptor is substantially evenly dispersed in the donor polymer.

8. The composite material according to claim 1, wherein the composite material is in the form of a flexible film.

9. The composite material according to claim 8, wherein the flexible film is a bulk heterojunction film.

10. A device, comprising:
an organic photovoltaic (OPV) layer comprising the composite material according to claim 1;
a first electrode disposed on the OPV layer;
a charge transport layer disposed under the OPV layer; and
a second electrode disposed under the charge transport layer,
wherein the OPV layer is disposed between the charge transport layer and the first electrode, and
wherein the charge transport layer is disposed between the second electrode and the OPV layer.

11. The device according to claim 10, further comprising a substrate on which the second electrode is disposed,
wherein the second electrode is disposed between the substrate and the charge transport layer.

12. The device according to claim 10, wherein the second electrode comprises indium tin oxide,
wherein the charge transport layer comprises SnO₂, and
wherein the first electrode comprises silver (Ag), gold (Au), or a combination thereof.

13. The device according to claim 10, wherein the charge transport layer is an electron transporting layer.

14. The device according to claim 10, wherein the second electrode is in direct physical contact with the charge transport layer,
wherein the charge transport layer is in direct physical contact with the OPV layer, and
wherein the OPV layer is in direct physical contact with the first electrode.

15. The device according to claim 10, wherein the device is flexible.

16. The device according to claim 10, wherein the donor polymer is P3HT and the non-fullerene acceptor is Y6,
wherein the OPV exhibits a rectification ratio in a range of from 3.6×10³ to 4×10³, and
wherein the device has a response time of 100 milliseconds (ms) or less when exposed to a 470 nanometer (nm) light pulse.

17. The device according to claim 10, further comprising a layer comprising a mechanoluminescent (ML) material,
wherein the layer comprising the ML material is disposed on and in direct physical contact with at least one of the first electrode, the OPV layer, the charge transport layer, and the second electrode, and
wherein the device is a sensor.
